(19) United States
(12) Patent Application Publication
(10) Pub. No.: US 2026/0223652 A1
(43) Pub. Date: Jul. 30, 2026

(54) METHODS OF FORMING MICROELECTRONIC DEVICES INCLUDING STAIRCASE STRUCTURES, AND RELATED MICROELECTRONIC DEVICES

(71) Applicant: Micron Technology, Inc., Boise, ID (US)

(72) Inventors: Yucheng Wang, Meridian, ID (US); Yiping Wang, Boise, ID (US); Collin Howder, Boise, ID (US); Jiewei Chen, Meridian, ID (US); Justin D. Shepherdson, Meridian, ID (US); Joshua Wolanyk, Ames, IA (US); Sidhartha Gupta, Boise, ID (US); John M. Meldrim, Boise, ID (US)

(21) Appl. No.: 19/441,335

(22) Filed: Jan. 6, 2026

Related U.S. Application Data
(60) Provisional application No. 63/750,153, filed on Jan. 27, 2025.

(51) Int. Cl. H10W 20/00; H10B 41/10; H10B 41/20; H10W 20/41; H10W 20/42; H10W 20/45; H10W 20/48

(52) U.S. Cl. CPC H10W 20/082; H10B 41/10; H10B 41/20; H10W 20/0595; H10W 20/076; H10W 20/42; H10W 20/435; H10W 20/455; H10W 20/48

(57) ABSTRACT

A method of forming a microelectronic device includes forming an etch-selective liner on a staircase structure having steps defined by preliminary tiers respectively including insulative material and sacrificial material. First openings are formed within a horizontal area of the staircase structure and vertically extending through the etch-selective liner and the preliminary tiers. The sacrificial material of the preliminary tiers are replaced with conductive material to form tiers respectively including the insulative material and the conductive material. Portions of the etch-selective liner horizontally adjacent to the first openings are laterally recessed to form second openings. The conductive contacts are within the second openings. The conductive contacts respectively includes a first portion vertically extending through the tiers and the etch-selective liner, and a second portion outwardly horizontally projecting from and unitary with the first portion.

### CROSS-REFERENCE TO RELATED APPLICATIONS

This application claims the benefit under 35 U.S.C. § 119(e) of U.S. Provisional Patent Application Ser. No. 63/750,153, filed Jan. 27, 2025, the disclosure of which is hereby incorporated herein in its entirety by this reference.

### TECHNICAL FIELD

The disclosure, in various embodiments, relates generally to the field of microelectronic device design and fabrication. More specifically, the disclosure relates to methods of forming microelectronic devices (e.g., memory devices, such as 3D NAND memory devices) including staircase structures, and related microelectronic devices.

### BACKGROUND

Microelectronic device designers often desire to increase the level of integration or density of features within a microelectronic device by reducing the dimensions of the individual features and by reducing the separation distance between neighboring features. In addition, microelectronic device designers often desire to design architectures that are not only compact, but offer performance advantages, as well as simplified designs.

One example of a microelectronic device is a memory device. A continuing goal of the electronics industry has been to increase the memory density (e.g., the number of memory cells per memory die) of memory devices, such as non-volatile memory devices (e.g., NAND flash memory devices). One way of increasing memory density in the non-volatile memory devices is to utilize vertical memory array (also referred to as a “three-dimensional memory array”) architectures. A conventional vertical memory array includes vertical memory strings extending through one or more stack structures having vertically alternating sequence of conductive structures and insulative structures. Each vertical memory string may include at least one select device coupled in series to a serial combination of vertically-stacked memory cells. Such a configuration permits a greater number of switching devices (e.g., transistors) to be located in a unit of die area (i.e., length and width of active surface consumed) by building the array upwards (e.g., vertically) on a die, as compared to structures with conventional planar (e.g., two-dimensional) arrangements of transistors.

In the three-dimension memory devices (e.g., 3D NAND memory device), the conductive structures of the tiers of the stack structures may function as control gates for access lines (e.g., word lines) of the memory cells. The access lines are electrically communicated with other conductive structures of the memory device so that the memory cells of the vertical memory strings can be selected for writing, reading, and erasing operation. One method of forming such an electrical communication includes forming so-called “staircase” structures at edges (e.g., horizontal ends) of the conductive structures of the stack structures of the memory device. The staircase structure includes individual “steps” defining contact regions upon which conductive contacts can be formed for electrical communication to the conductive structures such as the access line of the memory cells.

As vertical memory array technology has advanced, additional memory density has been provided by forming vertical memory arrays to include stacks comprising additional tiers of conductive structures and, hence, additional staircase structures and/or additional steps in individual staircase structures associated therewith. As the height of the stacks increases to facilitate additional memory cells in the vertical memory arrays, the stacks may be prone to toppling or collapse during various processing acts. For example, during replacement gate processing acts, the stacks may be subject to tier collapse during or after removal of portions of the tiers to be replaced with the conductive structures. Collapse of the portions of the stacks may reduce reliability of the vertical memory strings.

### BRIEF DESCRIPTION OF THE DRAWINGS

FIGS. 1A through 11B are simplified, partial top-down views (FIGS. 1A, 6, 8 and 11B) and simplified, partial vertical cross-sectional views (FIGS. 1B, 2-5, 7, 9, 10 and 11A) illustrating different processing stages of a method of forming a microelectronic device, in accordance with embodiments of the disclosure;

FIG. 12 is a simplified, partial cutaway perspective view of a microelectronic device, in accordance with embodiments of the disclosure; and

FIG. 13 is a schematic block diagram of an electronic system, in accordance with embodiments of the disclosure.

### DETAILED DESCRIPTION

The following description provides specific details, such as material types, material thicknesses, and processing conditions in order to provide a thorough description of embodiments of the disclosure. However, a person of ordinary skill in the art will understand that embodiments of the present disclosure may be practiced without employing these specific details. Indeed, the embodiments of the present disclosure may be practiced in conjunction with conventional fabrication techniques employed in the industry. In addition, the description provided herein does not form a complete process flow for forming a semiconductor device structure, and the semiconductor device structures described below do not form a complete semiconductor device. Only those process acts and structures necessary to understand the embodiments of the present disclosure are described in detail below. Additional acts to form the complete semiconductor device may be performed by conventional fabrication techniques.

Drawings presented herein are for illustrative purposes only, and are not meant to be actual views of any particular material, component, structure, electronic device, or electronic system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. Furthermore, the drawings accompanying the application are for illustrative purposes only, and are thus not necessarily drawn to scale. Elements common between figures may retain the same numerical designation. While the materials described and illustrated herein may be formed as layers, the materials are not limited thereto and may be formed in other three-dimensional configurations.

As used herein, the singular forms “a,” “an,” and “the” are intended to include the plural forms as well, unless the context clearly indicates otherwise.

As used herein, “and/or” includes any and all combinations of one or more of the associated listed items.

As used herein, the term “may” with respect to a material, structure, feature, or method act indicates that such is contemplated for use in implementation of an embodiment of the disclosure and such term is used in preference to the more restrictive term “is” so as to avoid any implication that other, compatible materials, structures, features, and methods usable in combination therewith should or must be excluded.

As used herein, relational terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the drawings. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, reference to an element as being “on” or “over” another element means and includes the element being directly on top of, directly adjacent to (e.g., directly laterally adjacent to, directly vertically adjacent to), directly underneath, or in direct contact with the other element. It also includes the element being indirectly on top of, indirectly adjacent to (e.g., indirectly laterally adjacent to, indirectly vertically adjacent to), indirectly underneath, or near the other element, with other elements present therebetween. In contrast, when an element is referred to as being “directly on” or “directly adjacent to” another element, there are no intervening elements present.

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, the term “about” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 108.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, “memory device” means and includes microelectronic devices exhibiting memory functionality, but not necessarily limited to memory functionality. Stated another way, and by way of example only, the term “memory device” means and includes not only memory (e.g., volatile memory, such as dynamic random access memory (DRAM); non-volatile memory, such as NAND memory), but also includes an application specific integrated circuit (ASIC) (e.g., a system on a chip (SoC)), an electronic device combining logic and memory, or a graphics processing unit (GPU) incorporating memory.

As used herein, “electronic device” includes, without limitation, a memory device, as well as a semiconductor device which may or may not incorporate memory, such as a logic device, a processor device, or a radiofrequency (RF) device. Further, an electronic device may incorporate memory in addition to other functions such as, for example, a so-called “system on a chip” (SoC) including a processor and memory, or an electronic device including logic and memory. The electronic device may, for example, be a 3D electronic device, such as a 3D NAND Flash memory device.

As used herein, “substrate” means and includes a base material or construction upon which additional materials are formed. The substrate may be, for example, a semiconductor substrate, a base semiconductor material on a supporting structure, a metal electrode or a semiconductor substrate having one or more materials, structures or regions formed thereon. The substrate may be a conventional silicon substrate, or other bulk substrate comprising a layer of semiconductive material. As used herein, the term “bulk substrate” means and includes not only silicon wafers, but also silicon-on-insulator (SOI) substrates, such as silicon-on-sapphire (SOS) substrates and silicon-on-glass (SOG) substrates, epitaxial layers of silicon on a base semiconductor foundation, or other semiconductor or optoelectronic materials, such as silicon-germanium (Si₁₋ₓGeₓ, where x is, for example, a mole fraction between 0.2 and 0.8), germanium (Ge), gallium arsenide (GaAs), gallium nitride (GaN), or indium phosphide (InP), among others. The substrate may be doped or undoped. By way of non-limiting example, a substrate may comprise at least one of silicon, silicon dioxide, silicon with native oxide, silicon nitride, a carbon-containing silicon nitride, glass, semiconductor, metal oxide, metal, titanium nitride, carbon-containing titanium nitride, tantalum, tantalum nitride, carbon-containing tantalum nitride, niobium, niobium nitride, carbon-containing niobium nitride, molybdenum, molybdenum nitride, carbon-containing molybdenum nitride, tungsten, tungsten nitride, carbon-containing tungsten nitride, copper, cobalt, nickel, iron, aluminum, and a noble metal.

As used herein, “conductive material” means and includes an electrically conductive material, such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe-and Ni-based alloy, a Co-and Ni-based alloy, an Fe-and Co-based alloy, a Co-and Ni-and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively-doped semiconductor material (e.g., conductively-doped polysilicon, conductively-doped germanium (Ge), conductively-doped silicon germanium (SiGe)). In addition, a “conductive structure” means and includes a structure formed of and including conductive material.

As used herein, a “insulative material” or a “dielectric material” means and includes an electrically insulative material, such one or more of at least one dielectric oxide material (e.g., one or more of a silicon oxide, phosphosilicate glass, borosilicate glass, borophosphosilicate glass, fluorosilicate glass, an aluminum oxide, a hafnium oxide, a niobium oxide, a titanium oxide, a zirconium oxide, a tantalum oxide, and a magnesium oxide), at least one dielectric nitride material (e.g., a silicon nitride), at least one dielectric oxynitride material (e.g., a silicon oxynitride), and at least one dielectric carboxynitride material (e.g., a silicon carboxynitride). As used herein, an “insulative structure” means and includes a structure formed of and including one or more insulative materials. As used herein, an “dielectric structure” means and includes a structure formed of and including one or more dielectric materials.

As used herein, “removal selectivity” or “selectively removable” means that a material exhibits a greater removal rate upon exposure to a given removing (e.g., etching) chemistry and/or process conditions relative to another material exposed to the same removal chemistry and/or process conditions. For example, the material may exhibit a removal rate that is at least about five (5) times greater than the removal rate of another material, such as a removal rate of about 10 times greater, about 20 times greater, about 40 times greater, about 50 times greater, 75 times greater, about 100 times greater, or more than 100 times greater than the removal rate of the another material. Removal chemistries and conditions (e.g., etch chemistries and etch conditions) for selectively removing a material relative to one or more other materials may be selected by a person of ordinary skill in the art.

Unless otherwise indicated, the materials described herein may be formed by conventional techniques including, but not limited to, spin coating, blanket coating, chemical vapor deposition (CVD), atomic layer deposition (ALD), plasma enhanced ALD, physical vapor deposition (PVD) (including sputtering, evaporation, ionized PVD, and/or plasma-enhanced CVD), or epitaxial growth. Alternatively, the materials may be grown in situ. Depending on the specific material to be formed, the technique for depositing or growing the material may be selected by a person of ordinary skill in the art. The removal of materials may be accomplished by any suitable technique including, but not limited to, etching (e.g., dry etching, wet etching, vapor etching), ion milling, abrasive planarization (e.g., chemical-mechanical planarization), or other known methods unless the context indicates otherwise.

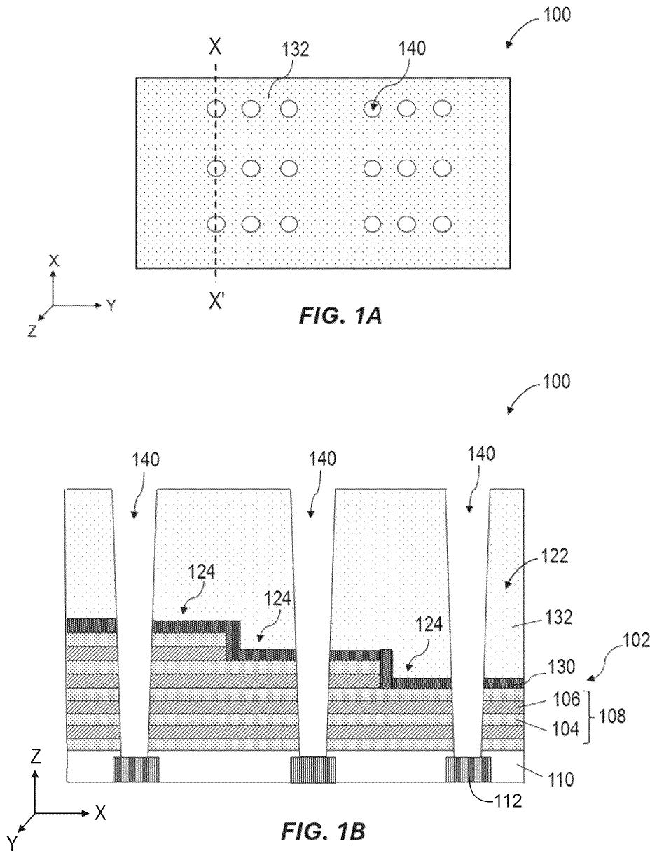

FIGS. 1A through 11B are simplified, partial top-down views (FIGS. 1A, 6, 8 and 11B) and simplified, partial vertical cross-sectional views (FIGS. 1B, 2-5, 7, 9, 10 and 11A) illustrating different processing stages of a method of forming a microelectronic device (e.g., a memory device, such as a three-dimensional (3D) NAND Flash memory device), in accordance with embodiments of the disclosure. With the description provided below, it will be readily apparent to one of ordinary skill in the art that the methods and structures described herein with reference to FIGS. 1A through 11B may be used in the formation and configuration of various devices and electronic systems. The methods of the disclosure may be used whenever it is desired to form a microelectronic device.

FIG. 1A is simplified, partial top-down view of the a microelectronic device structure 100 at a processing stage of a method of forming a microelectronic device of the disclosure. FIG. 1B is a simplified, partial vertical cross-sectional view of the microelectronic device structure 100 of FIG. 1A along the dashed line X-X′ shown in FIG. 1A. For clarity and ease of understanding of the drawings and related description, not all features depicted in one of FIGS. 1A and 1B are depicted in the other of FIGS. 1A and 1B.

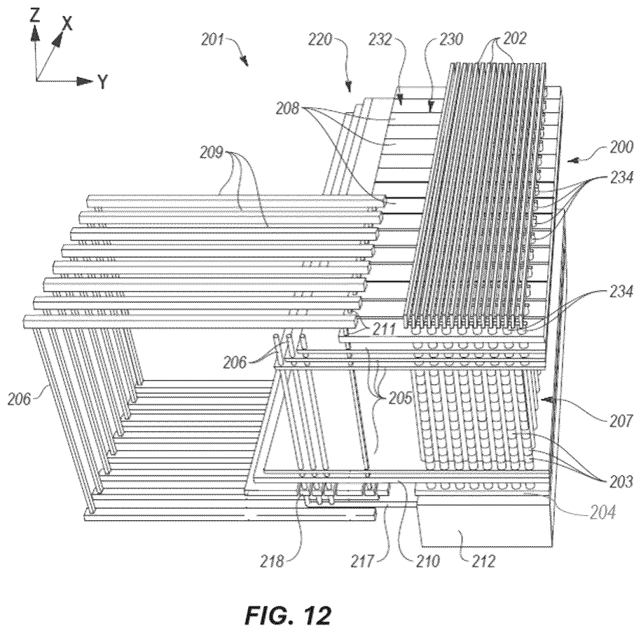

Referring collectively to FIGS. 1A and 1B, the microelectronic device structure 100 may be formed to include a preliminary stack structure 102 vertically overlying (e.g., in the Z-direction) a substrate 110. The substrate 110 may include one or more source structures (e.g., a source plate, source lines) therein. The source structure may be configured to be operatively associated with vertically extending strings of memory cells within a memory array region of the microelectronic device structure 100, as described later in FIG. 12.

The preliminary stack structure 102 may be formed to include a vertically alternating sequence of insulative material 104 and sacrificial material 106 arranged in tiers 108. Each of the tiers 108 of the preliminary stack structure 102 may include a level of the insulative material 104 vertically neighboring a level of the sacrificial material 106. Within the preliminary stack structure 102, the insulative material 104 may be vertically interleaved with the sacrificial material 106.

The insulative material 104 of the preliminary stack structure 102 may be formed of and include at least one insulative material having removal selectivity (e.g., etch selectivity) relative to the sacrificial material 106 of the preliminary stack structure 102. In some embodiments, the insulative material 104 is formed of and includes silicon oxide (e.g., SiO₂).

The sacrificial material 106 of the preliminary stack structure 102 may be formed of and include at least one material (e.g., additional insulative material) that can be removed selectively relative to the insulative material 104 of the preliminary stack structure 102. As a non-limiting example, the sacrificial material 106 may be removed at etch rate that is at least two times (2×) faster than an etch rate of the insulative material 104 during mutual exposure to an etchant (e.g., a wet etchant). In some embodiments, the sacrificial material 106 is formed of and includes silicon nitride (e.g., Si₃N₄).

In some embodiments, a number (e.g., quantity) of tiers 108 of the preliminary stack structure 102 is within a range of from about thirty-two (32) to about one thousand twenty-four (1024) of the tiers 108 (e.g., from about sixty-four (64) tiers 108 to about five hundred and twelve (512) tiers 108, from about one hundred twenty-eight (128) tiers 108 tiers 108 to about two hundred fifty-six (256) tiers 108). However, the disclosure is not so limited, and the preliminary stack structure 102 may include a different quantity of the tiers 108. In addition, in some embodiments, the preliminary stack structure 102 overlies a deck structure comprising additional tiers 108 of the insulative material 104 and the sacrificial material 106. The preliminary stack structure 102 may or may not be vertically separated from the preliminary stack structure 102 by an interdeck insulative material.

The microelectronic device structure 100 may include a staircase region and an array region horizontally (e.g., in the X-direction) neighboring the staircase region. The array region may include memory pillar structures (e.g., cell pillar structures) employed to form portions of vertically extending strings of memory cells (e.g., strings of NAND memory cells), as described in further detail with reference to FIG. 12. Features within the array region of the microelectronic device structure 100 may be formed before, during (e.g., substantially simultaneous with), or after formation of features within the staircase region.

At least one staircase structure 122 may be formed within the preliminary stack structure 102 of the microelectronic device structure 100. The staircase structure 122 may be positioned within horizontal boundaries (e.g., a horizontal area) of the staircase region of the microelectronic device structure 100.

The staircase structure 122 may be formed to include steps 124 comprising edges (e.g., horizontal ends) of the tiers 108 of the preliminary stack structure 102. For clarity and ease of understanding the drawings and associated description, FIG. 1B illustrates a particular quantity (e.g., three) of steps 124 in the staircase structure 122. However, it will be understood that the staircase structure 122 may include a greater quantity of steps 124 than those illustrated. For example, the staircase structure 122 may include greater or equal to eight (8) of the steps 124, greater than or equal to sixteen (16) of the steps 124, greater or equal to than thirty-two (32) of the steps 124, greater than or equal to sixty-four (64) of the steps 124, greater than or equal to one-hundred twenty-eight (128) of the steps 124, greater than or equal to two-hundred fifty-six (256) of the steps 124, greater than or equal to five-hundred twelve (512) of the steps 124, or greater than or equal to one-thousand twenty-four (1024) of the steps 124.

In some embodiments, the staircase structure 122 forms a portion of a stadium structure including opposing staircase structures 122 each having steps 124 defined by horizontal ends of the tiers 108 of the preliminary stack structure 102. In some embodiments, multiple (e.g., more than one) stadium structures are formed to be positioned at substantially the same vertical locations as one another within the preliminary stack structure 102. In some other embodiments, one stadium structure is formed to be positioned at different vertical locations than other stadium structures within the preliminary stack structure 102.

An etch-selective liner structure 130 may be formed on or over the staircase structure 122. The etch-selective liner structure 130 may be formed of and include a material having a different removal rate than a removal rate of the insulative material 104 of the preliminary stack structure 102 and a removal rate or the sacrificial material 106 of the preliminary stack structure 102 upon mutual exposure to an etchant.

The etch-selective liner structure 130 may be formulated to achieve a desired removal selectivity in relative to the insulative material 104 of the preliminary stack structure 102. In some embodiments, the etch-selective liner structure 130 exhibits a removal rate that is at least about three (3) times (3×) greater than a removal rate of the insulative material 104 of the preliminary stack structure 102. In some embodiments, the etch-selective liner structure 130 exhibits a removal rate that is at least about five (5) times (5×) greater than a removal rate of the insulative material 104 of the preliminary stack structure 102. The etch-selective liner structure 130 may, for example, have a removal rate that is about ten (10) times greater, about 20 times greater, about 40 times greater, about 50 times greater, 75 times greater, about 100 times greater, or more than 100 times greater than a removal rate of the insulative material 104 of the preliminary stack structure 102 during mutual exposure to an etchant.

The sacrificial material 106 of the preliminary stack structure 102 may be selectively removable in relative to the etch-selective liner structure 130. In some embodiments, the sacrificial material 106 of the preliminary stack structure 102 exhibits a removal rate that is at least about three (3) times (3×) greater than a removal rate of the etch-selective liner structure 130. In some embodiments, the sacrificial material 106 of the preliminary stack structure 102 exhibits a removal rate that is at least about five (5) times (5×) greater than a removal rate of the etch-selective liner structure 130. The sacrificial material 106 of the preliminary stack structure 102 may, for example, exhibit a removal rate that is about ten (10) times greater, about 20 times greater, about 40 times greater, about 50 times greater, 75 times greater, about 100 times greater, or more than 100 times greater than a removal rate of the etch-selective liner structure 130 during mutual exposure to an etchant.

Depending on material compositions of the insulative material 104 and the sacrificial material 106 of the preliminary stack structure 102, the etch-selective liner structure 130 may, for example, be formed of and include one or more of an oxynitride material (e.g., silicon oxynitride); a phosphorus-doped oxynitride material (e.g., phosphorus-doped silicon oxynitride); a carbon-doped oxynitride material (e.g., carbon-doped silicon oxynitride, silicon oxycarbonitride); a carbon-doped nitride material (e.g., carbon-doped silicon nitride, silicon carbonitride); a boron-doped material (e.g., boron-doped silicon oxide, boron-doped silicon nitride); a phosphorus-doped material (e.g., phosphorus-doped silicon oxide, phosphorus-doped silicon nitride, phosphorus-doped silicon oxynitride); boron nitride; and gallium nitride.

If the etch-selective liner structure 130 is doped, a dopant concentration within the etch-selective liner structure 130 may be tailored to achieve the desired removal selectivity of the etch-selective liner structure 130 relative to the insulative material 104 and the sacrificial material 106 of the preliminary stack structure 102. In some embodiments, the etch-selective liner structure 130 is a doped material, and the dopant thereof comprises one or more of carbon, phosphorus, and boron.

The etch-selective liner structure 130 may be substantially homogeneous or may be heterogeneous throughout one or more dimensions (e.g., a vertical dimension, one or more horizontal dimensions) thereof. In some embodiments, the etch-selective liner structure 130 is substantially homogeneous throughout a thickness thereof. In additional embodiments, the etch-selective liner structure 130 is heterogeneous throughout a thickness thereof.

In some embodiments, the etch-selective liner structure 130 includes from about 10 atomic percent (at. %) to about 65 at. % of oxygen; from about 0 at. % to about 40 at. % of nitrogen; from about 0 at. % to about 15 at. % of phosphorus; from about 0 at. % to about 40 at. % of carbon; and silicon in an amount to complete 100 at. % of the etch-selective liner structure 130.

In some embodiments, the insulative material 104 of the preliminary stack structure 102 comprises silicon oxide, the sacrificial material 106 of the preliminary stack structure 102 comprises silicon nitride, and the etch-selective liner structure 130 comprises phosphorus-doped silicon oxynitride. The phosphorus-doped silicon oxynitride of the etch-selective liner structure 130 may, for example, include from about 25 at. % to about 40 at. % nitrogen, from about 10 at. % to about 65 at. % oxygen, and from at 2 at. % to about 10 at. % phosphorus.

A thickness (e.g., vertical dimension in the Z-direction normal to a tread of one of the steps 124 of the staircase structure 122) of the etch-selective liner structure 130 may by larger than a thickness (e.g., vertical dimension in the Z-direction) of the sacrificial material 106 of the preliminary stack structure 102. In some embodiments, a thickness of the etch-selective liner structure 130 is at least about 5 nanometers (nm). In some embodiments, a thickness of the etch-selective liner structure 130 is at least about 10 nm.

An insulative fill material 132 may be formed to at least partially (e.g., substantially) fill at least one valley (e.g., space, gap, trench) vertically overlying and within a horizontal area of the staircase structure 122. The insulative fill material 132 may be formed of and include a material exhibiting removal selectivity in relative to one or more of the insulative material 104 of the preliminary stack structure 102, the sacrificial material 106 of the preliminary stack structure 102, the etch-selective liner structure 130, and additional materials (e.g., additional insulative materials, additional conductive materials) formed during subsequent processing of the microelectronic device structure 100. In some embodiments, the insulative fill material 132 comprises an insulative material, such as one or more of the materials described above with reference to the insulative material 104 (e.g., silicon oxide) of the preliminary stack structure 102.

Openings 140 (e.g., contact openings) may be formed to vertically extend through the preliminary stack structure 102. The openings 140 may be positioned with a horizontal area of the staircase structure 122. For example, an individual opening 140 may be formed to be horizontally positioned within a horizontal area of a tread of a tread of an individual step 124 of the staircase structure 122. To form the openings 140, portions of each of the insulative fill material 132, the etch-selective liner structure 130, as well as the insulative material 104 and the sacrificial material 106 of at least some of the tiers 108 of the preliminary stack structure 102 may be removed by exposing the respective materials to wet etch chemistries and/or dry etch chemistries, for example, in one or more material removal processes.

In some embodiments, as shown in FIG. 1B, the openings 140 may be formed to extend from an upper surface of the insulative fill material 132 to the conductive routing structures 112 underlying the preliminary stack structure 102. The openings 140 may be contact openings (e.g., word line contact openings, select line contact openings), which are employed in later processing stages to form contacts (e.g., word line contacts, select line contacts).

In some embodiments, the openings 140 extend vertically through an entire vertical extent (e.g., a height) of the preliminary stack structure 102. Thus, a height of each of the openings 140 in the vertical direction (e.g., the Z-direction) may be the same. Manufacturing processes may be simplified by forming the openings 140 to extend vertically through an entire height of the preliminary stack structure 102, without forming the openings 140 to extend vertically to varying (e.g., differing) depths of the preliminary stack structure 102 corresponding to various locations of the individual steps 124 of the staircase structure 122.

Although FIG. 1B shows all of the openings 140 as extending vertically through an entire height of the preliminary stack structure 102, the disclosure is not limited and at least one of the openings 140 may not extend vertically through the entire height of the preliminary stack structure 102. An individual opening 140 may, for example, be formed to extend from an upper surface of the insulative fill material 132 and to terminate at or within an individual tier 108 of the preliminary stack structure 102.

In some embodiments, one or more (e.g., a group) of the openings 140 are employed as drain-side select gate (SGD) contact openings, which are employed during later processing stages to form one or more SGD contacts. In such embodiments, the one or more of the openings 140 may not extend through an entire height of the preliminary stack structure 102. Rather, the openings 140 may terminate at or within tiers 108 of the preliminary stack structure 102 as SGD tiers. In additional embodiments, one or more (e.g., a group) of the openings 140 are employed as word line contact openings, which are employed during later processing stages to form one or more word line contacts. In such embodiments, the one or more of the openings 140 may extend through the entire height of the preliminary stack structure 102. In further embodiments, one or more (e.g., a group) of the openings 140 are employed as source-side select gate (SGS) contact openings, which are employed during later processing stages to form one or more SGS contacts. In such embodiments, the one or more of the openings 140 may extend through the entire height of the preliminary stack structure 102.

Horizontal dimensions an individual opening 140 may be relatively smaller than that of a treads of an individual step 124 of the staircase structure 122. For example, a diameter an individual opening 140 may be within a range of from about 100 nanometers (nm) to about 500 nm, such as from about 100 nm to about 150 nm, from about 150 nm to about 250 nm, from about 250 nm to about 350 nm, or from about 350 nm to about 500 nm. Horizontal dimensions of the openings 140 may be selected and tailored to effect desirable geometric configurations (e.g., sizes and shapes) to features (e.g., contact structures) to be formed therein.

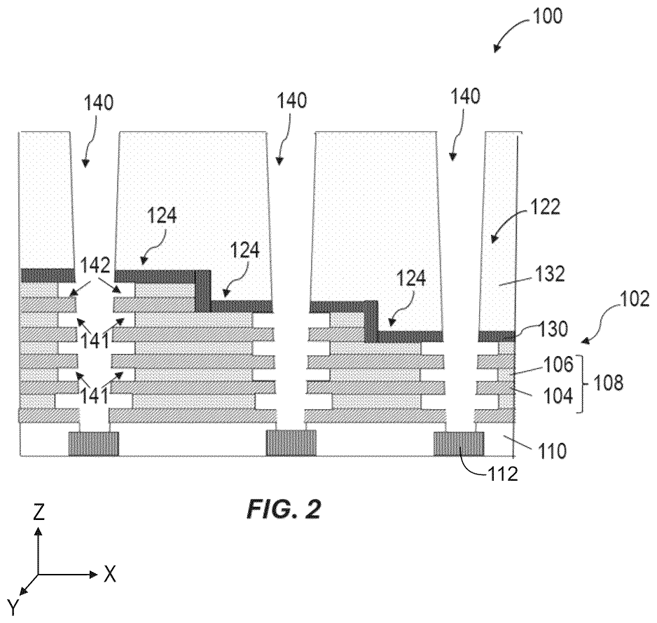

Referring next to FIG. 2, lateral portions (e.g., in the X-direction, in the Y-direction) of the sacrificial material 106 of the preliminary stack structure 102 may be selectively removed through the openings 140 to form first lateral recesses 141 and second lateral recesses 142 vertically overlying the first lateral recesses 141. Each of the first lateral recesses 141 is in communication with a respective one of the openings 140, and may be defined vertically (e.g., in the Z-direction) by two levels of insulative material 104 of the preliminary stack structure 102. Each of the second lateral recesses 142 is in communication with a respective one the openings 140, and may be defined vertically (e.g., in the Z-direction) by a portion of the etch-selective liner structure 130 and the insulative material 104 of an uppermost one of the tiers 108 of the preliminary stack structure 102. By way of non-limiting example, portions of the sacrificial material 106 of the preliminary stack structure 102 may be exposed to an etchant (e.g., a wet etchant) through the openings 140 to selectively remove the portions of the sacrificial material 106 with respect to the insulative material 104 of the preliminary stack structure 102 and the etch-selective liner structure 130. In some embodiments, the sacrificial material 106 of the tier 108 is exposed to phosphoric acid (H₃PO₄) to selectively remove portions of the sacrificial material 106 proximate the openings 140.

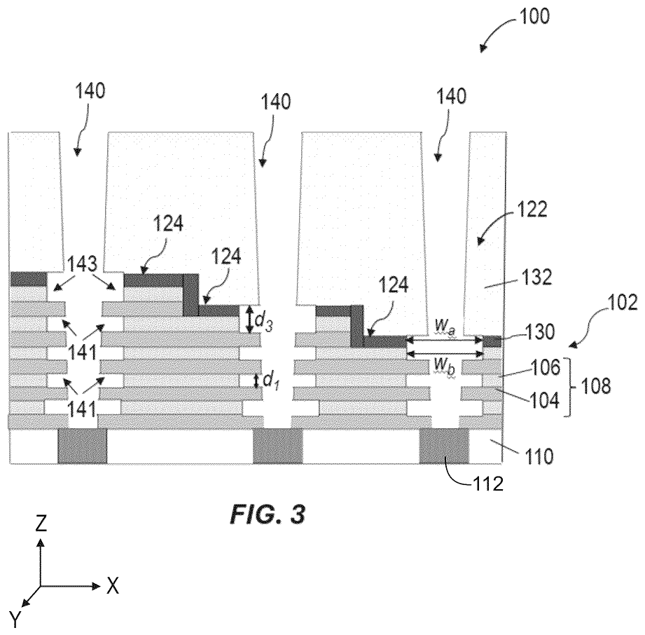

Referring next to FIG. 3, portions of the etch-selective liner structure 130 vertically overlying and horizontally overlapping the second lateral recesses 142 may be selectively removed through the openings 140 to form third lateral recesses 143. The third lateral recesses 143 may each be in communication with a respective one of the openings 140 and may vertically overlie and horizontally overlap a group of the first lateral recesses 141 also in communication with the respective one of the openings 140. A vertical dimension d₃ of an individual third lateral recess 143 is larger than a vertical dimension d₁ of an individual first lateral recess 141 thereunder. Horizontal boundaries of the third lateral recess 143 may be defined by remaining, horizontally neighboring portions of the etch-selective liner structure 130 and the sacrificial material 106 of the uppermost tier 108 of the preliminary stack structure 102. Vertical boundaries of an individual the third lateral recess 143 may be defined by remaining, vertically neighboring portions of the insulative fill material 132 and the insulative material 104 of the uppermost tier 108 of the preliminary stack structure 102.

FIG. 3 illustrates that an outer horizonal boundary of an individual third lateral recess 143 operatively associated with an individual opening 140 is substantially coplanar with horizonal boundaries of a group of underlying first lateral recess 141 operatively associated with the opening 140. However, the disclosure is not limited and the horizonal boundary of the third laterally recess 143 may not be coplanar with the horizonal boundary of at least one of the first lateral recesses 141 operatively associated with the opening 140.

Furthermore, a distance Wₐ between remaining, horizontally neighboring portions of the etch-selective liner structure 130 partially defining outer horizontal boundaries of an individual third lateral recess 143 may be substantially the same as a distance W_{b} between the remaining, horizontally neighboring portions of the sacrificial material 106 of the uppermost tier 108 partially defining the outer horizontal boundaries of the third lateral recess 143. In other words, the distance Wₐ may be substantially equal to the distance W_{b}. However, the disclosure is not limited and the distance Wₐ may be different than (e.g., larger than) the distance W_{b}.

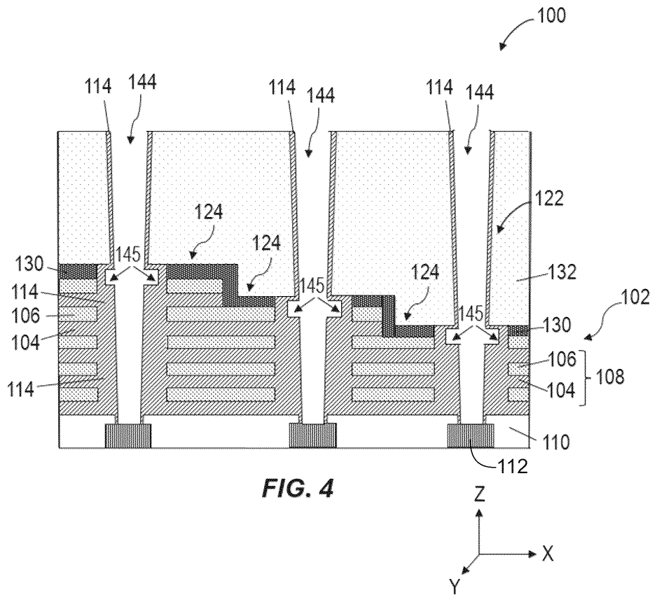

Referring next to FIG. 4, an insulative liner material 114 may be formed in the openings 140 (FIG. 3), the first lateral recesses 141 (FIG. 3), and the third lateral recesses 143 (FIG. 3). The insulative liner material 114 may directly contact surfaces of remaining portions of the insulative fill material 132, the etch-selective liner structures 130, and the tiers 108 of the preliminary stack structure 102 defining boundaries of the openings 140 (FIG. 3), the first lateral recesses 141 (FIG. 3), and the third lateral recesses 143 (FIG. 3). The insulative liner material 114 may substantially fill the first lateral recesses 141 (FIG. 3) without completely filling the openings 140 (FIG. 3). The insulative liner material 114 may also partially fill the third lateral recesses 143 (FIG. 3). Since the vertical dimension d₃ (FIG. 3) of an individual the third lateral recess 143 (FIG. 3) is larger than a vertical dimension d₁ (FIG. 3) of respective ones of the first lateral recesses 141 (FIG. 3), the third lateral recesses 143 (FIG. 3) are not completely filled with the insulative liner material 114, resulting in a formation of first lateral openings 145 from remaining portions of the third lateral recesses 143 (FIG. 3). The first lateral openings 145 may be in communication with modified openings 144 comprising remaining, unfilled portions of the openings 140 (FIG. 3).

Accordingly, the microelectronic device structure 100 at the processing stage of FIG. 4 may include modified openings 144 extending vertically through the preliminary stack structure 102, and first lateral openings 145 in communication with (e.g., outwardly horizontally extending from) the modified openings 144.

The insulative liner material 114 may be formed by conventional techniques, such as one or more of in situ growth, CVD, ALD, and PVD using conventional processing equipment. In some embodiments, the insulative liner material 114 is formed (e.g., deposited) using a single ALD process or a single CVD process.

The insulative liner material 114 may be formed of and include one or more of the materials described above with reference to the insulative material 104 (e.g., silicon oxide) of the preliminary stack structure 102. For example, the insulative liner material 114 may be formed of and include an insulative material that is different than, and that exhibits removal selectivity with respect to, one or more of the sacrificial material 106 of the preliminary stack structure 102 and the etch-selective liner structure 130. In some embodiments, the insulative liner material 114 is formed of and includes a single high quality silicon oxide material, such as an ALD SiOₓ. For example, the insulative liner material 114 may be a substantially uniform and substantially conformal silicon oxide material (e.g., a substantially uniform and substantially conformal silicon dioxide material) so that substantially no voids are present in the insulative liner material 114.

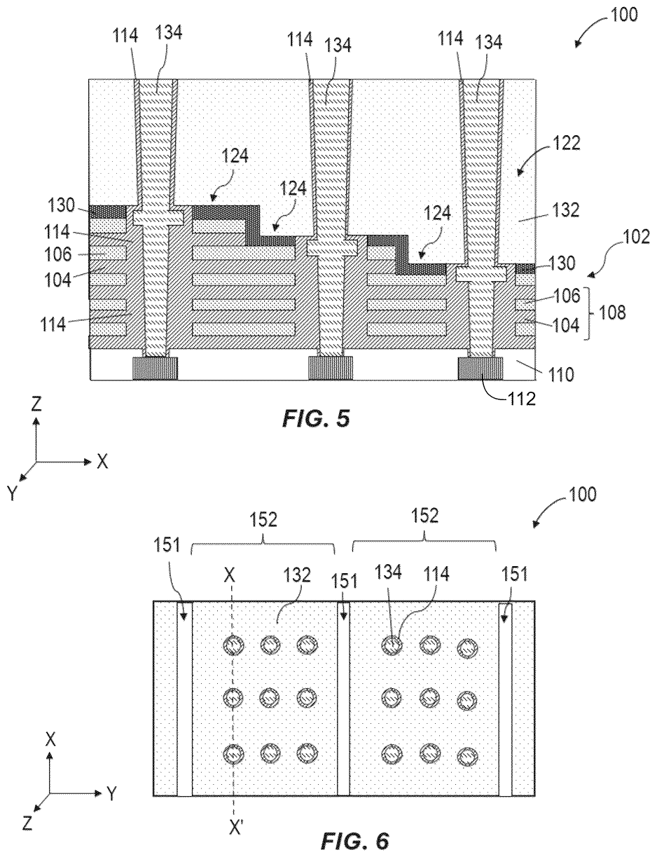

Referring next to FIG. 5, a sacrificial fill material 134 may be formed within the modified openings 144 (FIG. 4) and the first lateral openings 145 (FIG. 4) to substantially fill the modified openings 144 and the first lateral openings 145. The sacrificial fill material 134 may, for example, be formed of and include silicon material, such as amorphous silicon and/or polycrystalline silicon. In some embodiments, the sacrificial fill material 134 is doped with one or more dopants, such as at least one N-type dopant (e.g., one or more of arsenic, phosphorous, antimony, and bismuth) or at least one P-type dopant (e.g., one or more of boron, aluminum, and gallium).

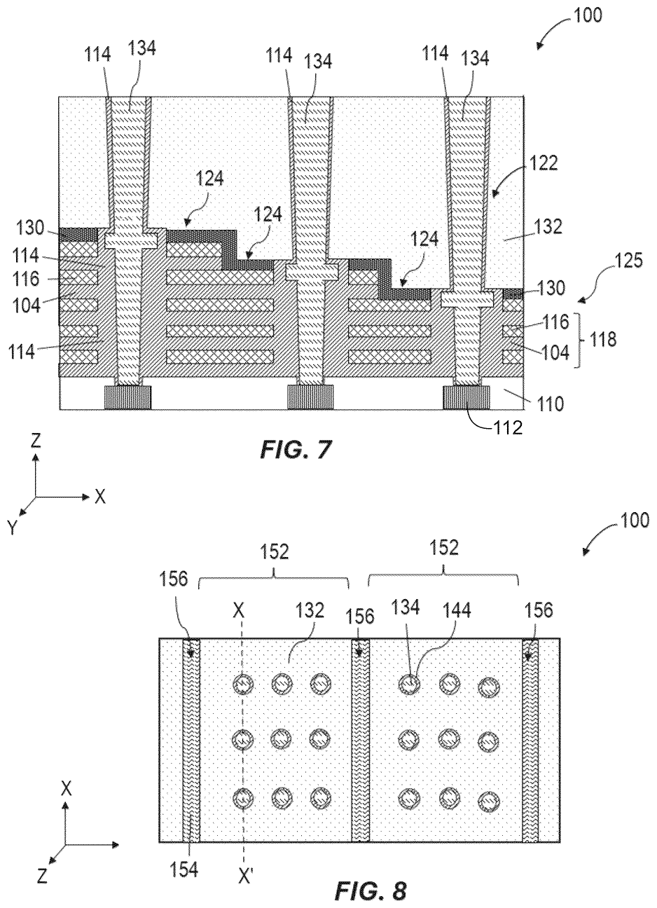

Referring next to FIG. 6, which is a simplified, partial top-down view of the microelectronic device structure 100 at a process stage following that previously described with reference to FIG. 5, slots 151 may be formed to extend vertically (e.g., in the Z-direction) through the insulative fill material 132 and the preliminary stack structure 102 (FIG. 5). The slots 151 may form blocks 152 separated from one another by the slot 151, wherein an individual block 152 includes, without limitation, a remaining portion of the preliminary stack structure 102 (FIG. 5) and a remaining portion of the insulative fill material 132. Although FIG. 6 illustrates only three (3) slots 151 and only two (2) blocks 152, the disclosure is not so limited. The microelectronic device structure 100 may include a plurality of (e.g., four, five, six, eight) blocks 152, each separated from a laterally neighboring (e.g., in the X-direction) block 152 by one of the slots 151. The slots 151 are also referred to herein as “replacement gate slots,” since they facilitate the replacement of the sacrificial material 106 (FIG. 5) of the preliminary stack structure 102 (FIG. 5) with conductive material, as will be described later with reference to FIG. 7.

While the replacement gate slots 151 are illustrated herein as being formed after formation of the sacrificial fill material 134 for clarity and ease of understanding of the drawings and related description, the slots 151 may, alternatively, be formed before formation of the sacrificial fill material 134. For example, the slots 151 may be formed during (e.g., substantially simultaneous with) formation of the openings 140 (FIG. 3).

Referring next to in FIG. 7, which is a simplified, partial vertical cross-sectional view of the microelectronic device structure 100 following the process stage of FIG. 6 (along the dashed line X-X′ shown in FIGS. 1A and 6), the sacrificial material 106 (FIG. 5) of the preliminary stack structure 102 (FIG. 5) may be selectively removed (e.g., exhumed) through the replacement gate slots 151 (FIG. 6), to create voids between vertically neighboring (e.g., in the Z-direction) levels of the insulative material 104 of the preliminary stack structure 102. The voids may then be filled with conductive material 116 to form a stack structure 125 including tiers 118 respectively including a level of the conductive material 116 and level of the insulative material 104. The stack structure 125 may be segmented into the blocks 152 (FIG. 6) by the slots 151 (FIG. 6).

In some embodiments, the conductive material 116 is formed to comprise one or more of tungsten, titanium, ruthenium, aluminum, and molybdenum. In additional embodiments, the conductive material 116 comprises conductively doped polysilicon. In further embodiments, the conductive material 116 is substantially free of silicon. The conductive material 116 may be formed a single (e.g., only one) material (e.g., only one elemental metal, only one single metal-containing material), or may be formed of and includes multiple materials (e.g., multiple elemental metals, multiple metal-containing materials). The conductive material 116 may be substantially homogeneous, or may be heterogeneous. In some embodiments, the conductive material 116 is substantially homogeneous. In additional embodiments, the conductive material 116 is heterogeneous.

Within an individual block 152 (FIG. 6), the conductive material 116 of at least one vertically lower tier 118 may be employed as at least one lower select gate structure (e.g., at least one source side select gate (SGS) structure) of the microelectronic device structure 100. In addition, within individual block 152 (FIG. 6), the conductive material 116 of at least one higher lower tier 118 may be employed for upper select gate structures(e.g., drain side select gate (SGD) structures) of the microelectronic device structure 100. Furthermore, within individual block 152 (FIG. 6), the conductive material 116 of some of the tier 118 may be employed for word line structures (e.g., local word line structures) of the microelectronic device structure 100.

Referring next to FIG. 8, which is a simplified, partial top-down view of the microelectronic device structure 100 at a process stage following that previously described with reference to FIG. 7, the replacement gate slots 151 (FIG. 6) may be filled with dielectric fill material 154 to form dielectric-filled slot structures 156.

The dielectric fill material 154 may be formed of and include dielectric material, such as one or more of dielectric oxide material (e.g., silicon oxide, phosphosilicate glass, borosilicate glass, borophosphosilicate glass, fluorosilicate glass), at least one dielectric nitride material (e.g., silicon nitride), at least one dielectric oxynitride material (e.g., silicon oxynitride), and at least one dielectric carboxynitride material (e.g., silicon carboxynitride). A material composition of the dielectric fill material 154 be substantially the same as a material composition of the insulative fill material 132 and/or the insulative material 104, or the material composition of the dielectric fill material 154 may be different than the material composition of the insulative fill material 132 and/or the insulative material 104. In some embodiments, the dielectric fill material 154 is formed of and includes silicon oxide (e.g., SiO₂).

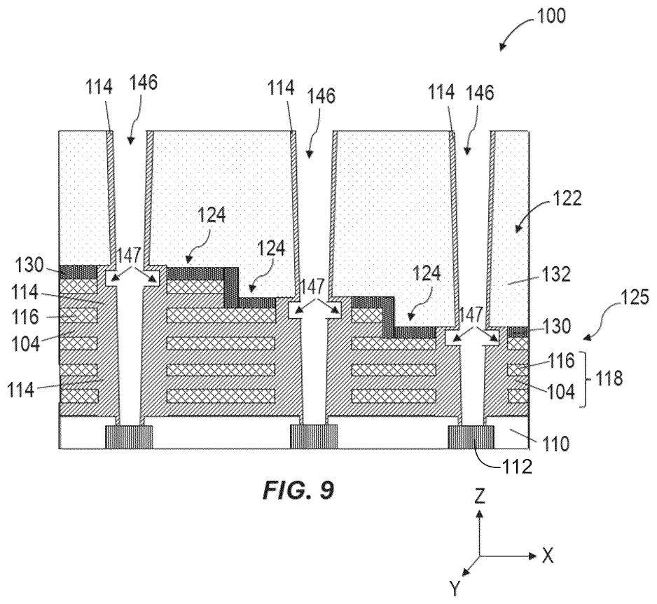

Referring next to FIG. 9, which is a simplified, partial vertical cross-sectional view of the microelectronic device structure 100 following the process stage of FIG. 8 (along the dashed line X-X′ shown in FIGS. 1A, 6, and 8), the microelectronic device structure 100 may be subjected to a material removal process to selectively remove the sacrificial fill material 134 (FIG. 8) and form second vertical openings 146 and second lateral openings 147 in communication with the second vertical openings 146. The second vertical openings 146 may respectively extend vertically through the stack structure 125 (e.g., through the stack structure 125 to the conductive routing structures 112).

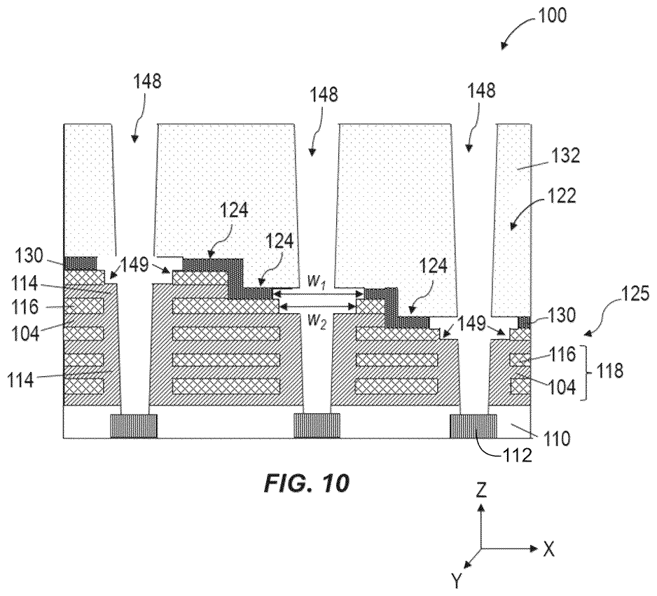

Referring next to FIG. 10, the microelectronic device structure 100 may be subjected to at least one material removal process to remove the insulative liner material 114 (FIG. 9) and to partially remove remaining portions of the etch-selective liner structure 130. In some embodiments, the removal process is performed by exposing the microelectronic device structure 100 to one or more etchants (e.g., dry etchants, wet etchants). The wet etchants may include one or more of phosphoric acid, acetic acid, nitric acid, hydrochloric acid, aqua regia, or hydrogen peroxide. In some embodiments, the microelectronic device structure 100 is subjected to a plasma etching process (e.g., an inductively coupled plasma (ICP) etching process) comprising one or more of hydrogen fluoride (HF), nitrogen trifluoride (NF₃), sulfur hexafluoride (SF₆), carbon tetrafluoride (CF₄), and another material. In additional embodiments, the microelectronic device structure 100 is subjected to a vapor etching process using a vapor stream of hydrofluoric acid (HF) and water.

The microelectronic device structure 100 of FIG. 10 includes third vertical openings 148 and third lateral openings 149 in communication with the third vertical openings 148. The third vertical openings 148 extend vertically through the stack structure 125 (e.g., through the stack structure 125 to the conductive routing structures 112). Outer horizontal boundaries of the third lateral openings 149 may be defined by remaining, horizontally neighboring portions of the etch-selective liner structure 130 and remaining, horizontally neighboring portions of the conductive material 116 of an uppermost tier 118 of the stack structure 125.

As shown in FIG. 10, a distance W₁ is a lateral distance between the remaining, horizontally neighboring portions of the etch-selective liner structure 130 partially defining outer horizontal boundaries of an individual third lateral opening 149, and a distance W₂ is a lateral distance between the horizontally neighboring portions of the conductive material 116 of the uppermost tier 118 partially defining outer horizontal boundaries of an individual third lateral opening 149. In some embodiments, the distance W₁ is larger than the distance W₂. In additional embodiments, the distance W₁ is substantially equal to the distance W₂.

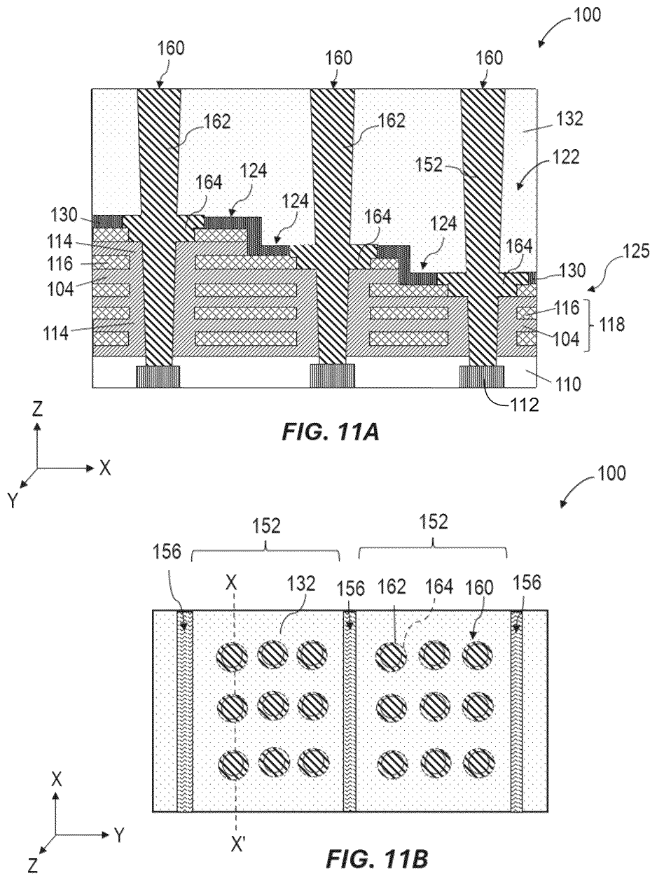

Referring next to FIG. 11A, the third vertical openings 148 (FIG. 10) and third lateral openings 149 (FIG. 10) may be substantially filled with conductive material to form conductive contacts 160 including vertical portions 162 (e.g., corresponding to the third vertical openings 148) and lateral portions 164 (e.g., corresponding to the third lateral openings 149) integral and continuous (e.g., unitary) with the vertical portions 162. The vertical portions 162 of the conductive contacts 160 extend vertically through the stack structure 125 (e.g., through the stack structure 125 to the conductive routing structures 112). The lateral portions 164 of the conductive contacts 160 may horizontally project outward from the vertical portions 162 of the conductive contacts 160. For an individual conductive contact 160, the lateral portion 164 thereof may be in physical contact with the insulative fill material 132, a portion of the etch-selective liner structure 130, and the conductive material 116 and the insulative material 104 of one of the tiers 118 of the stack structure 125 vertically proximate (e.g., directly vertically adjacent) the portion of the etch-selective liner structure 130. As shown in FIG. 11A, each of the conductive contacts 160 may be within a horizontal area of a tread of an individual step 124 of the staircase structure 122, although other configurations may be contemplated. Lateral dimension of the step 124 may be relatively larger than lateral dimensions of the conductive contact 160 (including the vertical portion 162 and the lateral portion 164 thereof) operatively associated therewith.

At least some of the conductive contacts 160 may exhibit a different geometric configuration (e.g., one or more different dimensions, a different shape) and/or different horizontal spacing than at least some other of the conductive contacts 160. In some embodiments, the microelectronic device structure 100 is substantially free of conductive contacts that terminate on the steps 124 of staircase structures 122 thereof.

Each of the conductive contacts 160 of the microelectronic device structure 100 may be formed to extend entirely through the vertical extent of the stack structure 125 and to terminate at the single vertical location in order to substantially reduce (e.g., substantially prevent) damage within the staircase structure 122 during fabrication. Accordingly, manufacturing processes may be simplified by forming the conductive contacts 160 to extend entirely through the vertical extent of the stack structure 125 and to terminate at a single location (e.g., at or within the conductive routing structures 112), without forming the conductive contacts 160 to extend to varying (e.g., differing) depths of the individual steps 124 of the staircase structure 122. In contrast, conventional microelectronic device structures include conductive contacts that terminate (e.g., land on) upper surfaces of individual steps of staircase structures, resulting in varying heights of conductive contacts throughout the staircase structures.

The conductive contacts 160 may be formed of and include conductive material. In some embodiments, the conductive contacts 160 respectively comprise tungsten. The conductive contacts 160 may or may not have substantially the same material composition as the conductive material 116 of the stack structure 125.

As shown in FIG. 11A, the conductive material 116 of a tier 118 of the stack structure 125 directly vertically adjacent to portions of the etch-selective liner structure 130 horizontally neighboring an individual conductive contact 160 is in physical contact with the conductive contact 160, but the conductive material 116 of other tiers 118 of the stack structure 125 do not contact the conductive contact 160. The conductive material 116 of the other tiers 118 of the stack structure 125 relatively more vertically distal from the portions of the etch-selective liner structure 130 may be electronically isolated from the conductive contact 160 by a remaining portion of the insulative liner material 114. The conductive contacts 160 may individually be in electrical communication with one of the conductive routing structures 112 and the conductive material 116 of one of the tiers 118 of the stack structure 125.

Accordingly, within a horizontal area of an individual block 152 (FIG. 11B), an individual conductive contact 160 may be configured to contact (e.g., physically contact, electrically contact) one of the conductive routing structures 112 and the conductive material 116 of one of the tiers 118 of the stack structure 125 at an individual step 124 of an individual staircase structure 122.

By forming the vertical portions 162 and the lateral portions 164 of the conductive contacts 160 at the same processing stage, the manufacturing processes may be simplified and costs may be reduced. The lateral portions 164 of the conductive contacts 160 may be formed during (e.g., substantially simultaneous with) formation of the vertical portions 162 of the conductive contacts 160 using a single, continuous CVD process or a single, continuous PVD process, for example, without forming the lateral portions 164 using an ALD process, similar to that used during the replacement gate process acts. Additionally, the methods and structures of the disclosure may reduce the risk of damage during the formation of devices of the disclosure and may effectuate increased yield and decreased current leakage (e.g., which may otherwise result from undesirable damage) as compared to conventional methods, conventional structures, and conventional devices.

FIG. 12 illustrates a simplified, partial cutaway perspective view of a portion of a microelectronic device 201 (e.g., a memory device, such as a dual deck 3D NAND Flash memory device) including a microelectronic device structure 200. The microelectronic device structure 200 may be substantially similar to the microelectronic device structure 100 following the processing stage previously described with reference to FIGS. 11A and 11B. As shown in FIG. 12, the microelectronic device structure 200 may include a staircase structure 220 (e.g., corresponding to the staircase structure 122 of FIG. 11A) defining contact regions for connecting conductive contacts 206 (e.g., corresponding to the conductive contacts 160 of FIGS. 11A and 11B) to conductive routing structures 218 (e.g., corresponding the conductive routing structures 112 of FIG. 11A) and to conductive material 205 (e.g., corresponding to the conductive material 116 of FIG. 11A) of tiers (e.g., corresponding to the tiers 118 of FIG. 11A) of a stack structure (e.g., corresponding to the stack structure 125 of FIG. 11A). The microelectronic device structure 200 may further include vertically extending strings 207 of memory cells 203 that are coupled to each other in series. The vertically extending strings 207 of memory cells 203 may extend vertically (e.g., in the Z-direction) and orthogonally to data lines 202, a source structure 204, first select gates 208 (e.g., upper select gates, drain select gates (SGDs)), select lines 209, and a second select gate 210 (e.g., a lower select gate, a source select gate (SGS)). The microelectronic device 201 may include multiple blocks 232 (e.g., corresponding to the blocks 152 of FIG. 11B) horizontally separated (e.g., in the Y-direction) from one another by filled slot structures 230 (e.g., corresponding to the dielectric-filled slot structures 156 of FIG. 11B).

Conductive contacts 211 may, optionally, electrically couple components to each other as shown. For example, the select lines 209 may be electrically coupled to the first select gates 208 by way of the conductive contacts 211. The microelectronic device 201 may also include a control unit 212 positioned under and within a horizontal area of the memory array including the vertically extending strings 207 of memory cells 203. The control unit 212 may include control logic devices configured to control various operations of other features (e.g., the vertically extending strings 207 of memory cells 203) of the microelectronic device 201. By way of non-limiting example, the control unit 212 may include one or more (e.g., each) of charge pumps (e.g., V_{CCP} charge pumps, V_{NEGWL} charge pumps, DVC2 charge pumps), delay-locked loop (DLL) circuitry (e.g., ring oscillators), V_{dd} regulators, drivers (e.g., string drivers), decoders (e.g., local deck decoders, column decoders, row decoders), sense amplifiers (e.g., equalization (EQ) amplifiers, isolation (ISO) amplifiers, NMOS sense amplifiers (NSAs), PMOS sense amplifiers (PSAs)), repair circuitry (e.g., column repair circuitry, row repair circuitry), I/O devices (e.g., local I/O devices), memory test devices, MUX, error checking and correction (ECC) devices, self-refresh/wear leveling devices, and other chip/deck control circuitry. The control unit 212 may be coupled to the data lines 202, the source structure 204, the conductive contacts 206, the first select gates 208, and the second select gates 210, without limitation. In some embodiments, the control unit 212 includes CMOS (complementary metal-oxide-semiconductor) circuitry. In such embodiments, the control unit 212 may be characterized as having a “CMOS under Array” (“CuA”) configuration, wherein the CMOS circuitry of a logic region is at least partially (e.g., substantially) positioned within horizontal areas of memory array regions of a microelectronic device structure 200. Additional conductive routing structures 217 may couple components (e.g., the conductive contacts 206, the conductive routing structures 218) to circuitry of the control unit 212.

The first select gates 208 may extend horizontally in a first direction (e.g., the X-direction) and may be coupled to respective first groups of vertical strings 207 of memory cells 203 at a first end (e.g., an upper end) of the vertical strings 207. The second select gate 210 may be coupled to the vertical strings 207 at a second, opposite end (e.g., a lower end) of the vertical strings 207 of memory cells 203.

The data lines 202 (e.g., digit lines, bit lines) may extend horizontally in a second direction (e.g., in the Y-direction) that is at an angle (e.g., perpendicular) to the first direction in which the first select gates 208 extend. Individual data lines 202 may be coupled to individual groups of the vertical strings 207 extending the second direction (e.g., the Y-direction) at the first end (e.g., the upper end) of the vertical strings 207 of the individual groups. Additional individual groups of the vertical strings 207 extending the first direction (e.g., the X-direction) and coupled to individual first select gates 208 may share a particular vertical string 207 thereof with individual group of vertical strings 207 coupled to an individual data line 202. Thus, an individual vertical string 207 of memory cells 203 may be selected at an intersection of an individual first select gate 208 and an individual data line 202. Accordingly, the first select gates 208 may be used for selecting memory cells 203 of the vertical strings 207 of memory cells 203.

The conductive material 205 (e.g., corresponding to the conductive material 116 of the microelectronic device structure 100) may extend in respective horizontal planes. The conductive material 205 may be stacked vertically, such that each conductive material 205 is coupled to at least some of the vertical strings 207 of memory cells 203, and the vertical strings 207 of the memory cells 203 extend vertically through the stack structure including the conductive material 205. The conductive material 205 may be coupled to or may form control gates of the memory cells 203.

The first select gates 208 and the second select gates 210 may operate to select a vertical string 207 of the memory cells 203 interposed between data lines 202 and the source structure 204. Thus, an individual memory cell 203 may be selected and electrically coupled to a data line 202 by operation of (e.g., by selecting) the appropriate first select gate 208, second select gate 210, and conductive material 205 that are coupled to the particular memory cell 203.

The staircase structure 220 may be configured to provide electrical connection between the conductive routing structures 206 and the conductive material 205 through the vertical conductive contacts 211. In other words, an individual conductive material 205 may be selected via the conductive routing structures 206 in electrical communication with a respective the conductive contact 211 in electrical communication with the conductive material 205. The data lines 202 may be electrically coupled to the vertical strings 207 through conductive contact structures 234.

Thus, in accordance with embodiments of the disclosure, a method of forming a microelectronic device includes forming an etch-selective liner on a staircase structure having steps defined by preliminary tiers respectively including insulative material and sacrificial material vertically adjacent the insulative material. The etch-selective liner has a different material composition than each of the insulative material and sacrificial material. First openings are formed within a horizontal area of the staircase structure and vertically extending completely through the etch-selective liner and the preliminary tiers. After forming the first openings, the sacrificial material of the preliminary tiers are replaced with conductive material to form tiers respectively including the insulative material and the conductive material vertically adjacent the insulative material. After forming the tiers, portions of the etch-selective liner horizontally adjacent to the first openings are laterally recessed to form second openings. The conductive contacts are within the second openings. The conductive contacts respectively includes a first portion vertically extending completely through the tiers and the etch-selective liner, and a second portion outwardly horizontally projecting from and unitary with the first portion. The second portion of the respective conductive contact is in physical contact with each of a section of the etch-selective liner and the conductive material of one of the tiers directly vertically underlying the section of the etch-selective liner.

Furthermore, in accordance with additional embodiments of the disclosure, a microelectronic device includes a stack structure comprising a vertically alternating sequence of conductive material and insulative material arranged in tiers. The microelectronic device also includes a staircase structure within the stack structure and having steps defined by edges of the tiers. The microelectronic device further includes etch-selective liner on the steps of the staircase structure and conductive contacts within a horizontal area of the staircase structure. The etch-selective liner comprises a different material than each of the conductive material and insulative material. Each of the conductive contacts comprises a first portion vertically extending completely through the etch-selective liner and the stack structure, and a second portion outwardly horizontally projecting from and unitary with the first portion. The second portion of the conductive contact is in physical contact with each of a section of the etch-selective liner and the conductive material of one of the tiers directly vertically underlying the section of the etch-selective liner.

In accordance with further embodiments of the disclosure, a method of forming a microelectronic device includes forming a preliminary stack structure comprising a vertically alternating sequence of insulative material and sacrificial material arranged in preliminary tiers. The method also includes forming a staircase structure having steps comprising edges of at least some of the preliminary tiers of the preliminary stack structure. An etch-selective liner is formed on the steps of the staircase structure and formulated to have etch selectivity relative to the insulative material and the sacrificial material during mutual exposure to an etchant. An opening is formed within a horizontal area of the staircase structure. The opening includes a first portion extending vertically through each of the etch-selective liner structure and the preliminary stack structure, and a second portion in communication with and outwardly horizontally projection from the first portion. An outer horizontal boundary of the second portion of the opening is partially defined by side surfaces of the etch-selective liner and the sacrificial material of one of the preliminary tiers directly vertically adjacent to the etch-selective liner. The sacrificial material of the tiers the preliminary stack structure is replaced with conductive material, and a conductive contact is formed within the opening.

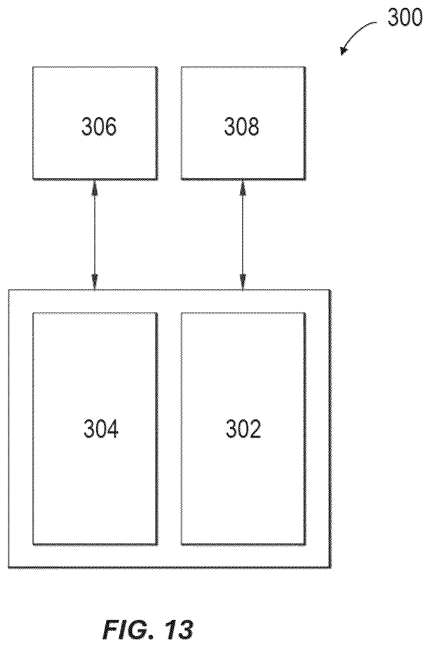

Microelectronic devices (e.g., the microelectronic device 201 of FIG. 2) including microelectronic device structures (e.g., the microelectronic device structure 100 of FIGS. 11A and 11B) of the disclosure may be included in embodiments of electronic systems of the disclosure. For example, FIG. 13 is a schematic block diagram of an electronic system 300, in accordance with embodiments of the disclosure. The electronic system 300 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPAD® or SURFACE® tablet, an electronic book, a navigation device, etc. The electronic system 300 includes at least one memory device 302. The memory device 302 may include, for example, an embodiment of a microelectronic device structure (e.g., the microelectronic device structure 100 of FIGS. 11A and 11B) and/or a microelectronic device (e.g., the microelectronic device 201 of FIG. 12) previously described herein.

The electronic system 300 may further include at least one electronic signal processor device 304 (often referred to as a “microprocessor”). The electronic signal processor device 304 may, optionally, include an embodiment of one or more of a microelectronic device and a microelectronic device structure previously described herein. The electronic system 300 may further include one or more input devices 306 for inputting information into the electronic system 300 by a user, such as, for example, a mouse or other pointing device, a keyboard, a touchpad, a button, or a control panel. The electronic system 300 may further include one or more output devices 308 for outputting information (e.g., visual or audio output) to a user such as, for example, a monitor, a display, a printer, an audio output jack, a speaker, etc. In some embodiments, the input device 306 and the output device 308 may comprise a single touchscreen device that can be used both to input information to the electronic system 300 and to output visual information to a user. The input device 306 and the output device 308 may communicate electrically with one or more of the memory device 302 and the electronic signal processor device 304.

While certain illustrative embodiments have been described in connection with the figures, those of ordinary skill in the art will recognize and appreciate that embodiments encompassed by the disclosure are not limited to those embodiments explicitly shown and described herein. Rather, many additions, deletions, and modifications to the embodiments described herein may be made without departing from the scope of embodiments encompassed by the disclosure, such as those hereinafter claimed, including legal equivalents. In addition, features from one disclosed embodiment may be combined with features of another disclosed embodiment while still being encompassed within the scope of the disclosure.

What is claimed is:

1. A method of forming a microelectronic device, comprising:
forming an etch-selective liner on a staircase structure having steps defined by preliminary tiers respectively including insulative material and sacrificial material vertically adjacent the insulative material, the etch-selective liner having a different material composition than each of the insulative material and sacrificial material;
forming first openings within a horizontal area of the staircase structure and vertically extending completely through the etch-selective liner and the preliminary tiers;
replacing the sacrificial material of the preliminary tiers with conductive material after forming the first openings to form tiers respectively including the insulative material and the conductive material vertically adjacent the insulative material; and
after forming the tiers, laterally recessing portions of the etch-selective liner horizontally adjacent to the first openings to form second openings; and
forming conductive contacts within the second openings and respectively including:
a first portion vertically extending completely through the tiers and the etch-selective liner; and
a second portion outwardly horizontally projecting from and unitary with the first portion, the second portion in physical contact with each of a section of the etch-selective liner and the conductive material of one of the tiers directly vertically underlying the section of the etch-selective liner.

2. The method of claim 1, further comprising:
selecting the insulative material of the preliminary tiers to comprise silicon oxide;
selecting the sacrificial material of the preliminary tiers to comprise silicon nitride; and
selecting the etch-selective liner to comprise one or more of silicon oxynitride, phosphorus-doped silicon oxynitride, carbon-doped silicon oxynitride, carbon-doped silicon nitride, carbon-doped silicon oxide, boron-doped silicon nitride, boron-dopped silicon oxide, phosphorus-doped silicon nitride, phosphorus-doped silicon oxide, phosphorus-doped silicon oxynitride, boron nitride, and gallium nitride.

3. The method of claim 2, further comprising selecting the etch-selective liner to comprise the phosphorus-doped silicon oxynitride.

4. The method of claim 1, wherein forming first openings within a horizontal area of the staircase structure and vertically extending completely through the etch-selective liner and the preliminary tiers comprises:
forming initial openings vertically extending completely through the etch-selective liner and the preliminary tiers; and
horizontally recessing portions of the etch-selective liner and the sacrificial material of the preliminary tiers horizontally adjacent to the initial openings to form the first openings, the first openings respectively comprising:
a first lateral recess continuous with one of the initial openings and vertically overlapping the etch-selective liner; and
second lateral recesses continuous with the one of the initial openings and respectively vertically underlying and horizontally overlapping the first lateral recess.

5. The method of claim 4, further comprising, prior to replacing the sacrificial material of the preliminary tiers with conductive material:
conformally forming an insulative liner material within the first openings, the insulative liner material completely filling the second lateral recesses and partially filling the first lateral recesses; and
substantially filling remaining portions of the first openings with additional sacrificial material.

6. The method of claim 5, wherein laterally recessing portions of the etch-selective liner horizontally adjacent to the first openings to form second openings comprises:
substantially removing the additional sacrificial material within the first openings;
partially removing the insulative liner material within the first openings as well as additional portions of the etch-selective liner to form the second openings, the second openings respectively including:
a first region vertically extending completely through the tiers and the etch-selective liner; and
a second region outwardly horizontally projecting from and unitary with the first region, the second region exposing each of the section of the etch-selective liner and the conductive material of the one of the tiers directed vertically underlying the section of the etch-selective liner.

7. The method of claim 6, further comprising forming the second region of respective ones of the second openings to have a stepped outer horizontal boundary partially defined by surfaces of the section of the etch-selective liner and the conductive material of the one of the tiers.

8. A microelectronic device, comprising:
a stack structure comprising a vertically alternating sequence of conductive material and insulative material arranged in tiers;
a staircase structure within the stack structure and having steps defined by edges of the tiers;
an etch-selective liner on the steps of the staircase structure and comprising a different material than each of the conductive material and insulative material; and
conductive contacts within a horizontal area of the staircase structure, each of the conductive contacts comprising:
a first portion vertically extending completely through the etch-selective liner and the stack structure; and
a second portion outwardly horizontally projecting from and unitary with the first portion, the second portion in physical contact with each of a section of the etch-selective liner and the conductive material of one of the tiers directly vertically underlying the section of the etch-selective liner.

9. The microelectronic device of claim 8, wherein the etch-selective line comprises one or more of an oxynitride material, a phosphorus-doped oxynitride material, a carbon-doped oxynitride material, a carbon-doped nitride material, a boron-dopped silicon oxide material, a boron-doped silicon nitride material, a phosphorus-dopped silicon oxide material, a phosphorus-dopped silicon oxynitride material, a phosphorus-doped silicon nitride material, a boron nitride material, and a gallium nitride material.

10. The microelectronic device of claim 8, wherein the etch-selective liner comprises silicon and:
from about 10 at. % to about 65 at. % of oxygen;
from about 0 at. % to about 40 at. % of nitrogen;
from about 0 at. % to about 15 at. % of phosphorus; and
from about 0 at. % to about 40 at. % of carbon.

11. The microelectronic device of claim 8, wherein the etch-selective liner is heterogeneous across a thickness thereof.

12. The microelectronic device of claim 8, further comprising conductive routing structures vertically underlying and in physical contact with bottom surfaces of the conductive contacts.

13. The microelectronic device of claim 8, wherein the second portion of respective ones of the conductive contacts has an outer horizontal boundary exhibiting a stepped vertical cross-sectional profile.

14. The microelectronic device of claim 8, wherein the conductive contacts have substantially a same vertical height as one another.

15. The microelectronic device of claim 8, wherein the second portion of respective ones of the conductive contacts comprises:
an upper region directly laterally adjacent the section of the etch-selective liner; and
a lower region underlying the upper region, the lower region directly laterally adjacent the conductive material of the one of the tiers.

16. The microelectronic device of claim 15, wherein a lateral dimension of the upper region is greater than or equal to that of the lower region.

17. The microelectronic device of claim 8, further comprising insulative liner material positioned between respective ones of the conductive contacts and the conductive material of additional ones of the tiers vertically below the second portion of each of the respective ones of the conductive contacts.

18. A method of forming a microelectronic device, comprising:
forming a preliminary stack structure comprising a vertically alternating sequence of insulative material and sacrificial material arranged in preliminary tiers;
forming a staircase structure having steps comprising edges of at least some of the preliminary tiers of the preliminary stack structure;
forming an etch-selective liner on the steps of the staircase structure and formulated to have etch selectivity relative to the insulative material and the sacrificial material during mutual exposure to an etchant;
forming an opening within a horizontal area of the staircase structure, the opening comprising:
a first portion extending vertically through each of the etch-selective liner and the preliminary stack structure; and
a second portion in communication with and outwardly horizontally projection from the first portion, an outer horizontal boundary of the second portion partially defined by side surfaces of the etch-selective liner and the sacrificial material of one of the preliminary tiers directly vertically adjacent to the etch-selective liner;
replacing the sacrificial material of the tiers the preliminary stack structure with conductive material; and
forming a conductive contact within the opening.

19. The method of claim 18, wherein forming the etch-selective liner on the steps of the staircase structure comprises conformally forming a phosphorus-doped dielectric oxynitride material on one of the steps of the staircase structure.

20. The method of claim 18, wherein forming an opening within a horizontal area of the staircase structure comprises substantially aligning a horizontal center of the opening with a horizontal center of one or the steps of the staircase structure.
